(19) United States
(12) Patent Application Publication
(10) Pub. No.: US 2024/0264249 A1
(43) Pub. Date: Aug. 8, 2024

(54) Expressive Music Synthesizer Interface with Two-Dimensional Flexure Motion Mechanism

(71) Applicant: Christopher Daniel GUICHET, San Francisco, CA (US)

(72) Inventor: Christopher Daniel GUICHET, San Francisco, CA (US)

(21) Appl. No.: 18/429,679

(22) Filed: Feb. 1, 2024

Related U.S. Application Data
(60) Provisional application No. 63/443,182, filed on Feb. 3, 2023.

(51) Int. Cl. G01R 33/07; G01L 9/00

(52) U.S. Cl. CPC G01R 33/072; G01L 9/008

(57) ABSTRACT

An expressive musical-instrument controller includes a flexure t that provides for two dimensions of motion, e.g., vertical and horizontal. The flexure includes a stationary base, a movable body, and a pair of parallel flexure beams mechanically connecting the movable body to the stationary base. Hall-effect sensors track the horizontal and vertical movement of the body relative to the stationary base. A bank of keys contoured to fingers is fixed to the movable body; the keys serve as capacitive triggers of notes. The player can move the bank of keys in two dimensions resulting in expressive control of trigger notes.

### RELATED APPLICATION

The present application is a non-provisional of provisional application 63/443,182, filed Feb. 3, 2023, and entitled “Musical Instrument interface with Two-Dimensional Continuous Express”. This provisional application is incorporated in full herein by reference.

### BACKGROUND

Analog and digital electronics have the capacity to generate limitless variety and quality of sounds in musical contexts. However, a musician must find a suitable interface to realize this potential. Electronic music instruments are sometimes considered repetitive and unemotional, perhaps due to their quantized human interfaces. Acoustic instruments, on the other hand, naturally afford subtle control that enables musicians to convey more emotion during performance.

Technology has also enabled electronic music interfaces with continuous sensors that do measure subtle musical gestures. These interfaces are called Expressive Controllers. Similar to acoustic instruments, Expressive Controllers each have their own advantages and disadvantages for making music. These benefits and drawbacks influence the sound that musicians produce on each Controller. Of particular interest are simple mechanical controllers that provide kinesthetic feedback so the player can feel an extent to which they have deviated from the baseline pitch or dynamic musical expression.

### BRIEF DESCRIPTION OF THE DRAWINGS

FIG. 1 is a schematic view of a flexure used in the Wigler to provide two dimensions of expression.

FIG. 2 is a diagram showing the flexure of FIG. 1 both with (right) and without (left) leftward horizontal force applied.

FIG. 3 is a diagram showing the flexure of FIG. 1 both with (right) and without (left) downward force applied.

FIG. 4 is a grayscale version of a photograph of a first Wiggler prototype in which the flexure is at rest.

FIG. 5 is a grayscale version of a photograph of the first Wiggler prototype in which the flexure is bent down and shifted to the left.

FIG. 6 is a grayscale version of a photograph of a second Wiggler showing keys that conform to a finger.

### DETAILED DESCRIPTION

The present invention provides an expressive controller using a flexure to provide kinesthetic feedback for two dimensions of motion. Keys mechanically connected to the flexure can be moved down and up (vertical) as well as left and right (horizontal), e.g., to expressive sonic volume and pitch. In a “Wiggler” embodiment the keys physically translate to provide tactile feedback of the expression state. There are two dimensions of zero friction motion and control, in a compact package with minimal parts. Wiggler fills a previously unexplored niche in this field: playing one monophonic note with expressive emotion.

To perform expressive control, Wiggler: 1) determines a note onset using touch sensitive keys; 2) allow a musician to physically move the keys and feedback to the default position; and 3) sense the vertical and horizontal motion. Wiggler uses a flexure to enable two dimensions of motion with one mechanism. The flexure has a stationary base, two parallel flexure beams, and a motion body. The flexure beams enable the motion body to translate +/−5 mm horizontally using S shape bending for linear motion. The same beams enable the motion body to move +/−5 mm vertically using C shaped bending for nearly linear motion. To avoid overstraining the flexure, the motion is limited using hard stops in the horizontal and vertical directions, two per direction. This makes a displacement-controlled fatigue problem, and the maximum motion is set to prevent fatigue failure up to millions of cycles.

Wiggler performs motion sensing using two magnets and two linear hall effect sensors to detect motion in two directions. Each magnet sensor pair measures one dimension of motion. The magnets are square to avoid motion cross talk. The square shape and magnetization direction of the magnet makes it optimal for measuring motion along the magnetization axis and rejects sensing on the perpendicular axis. A microprocessor records these expressive signals and uses them as real time sound generation parameters.

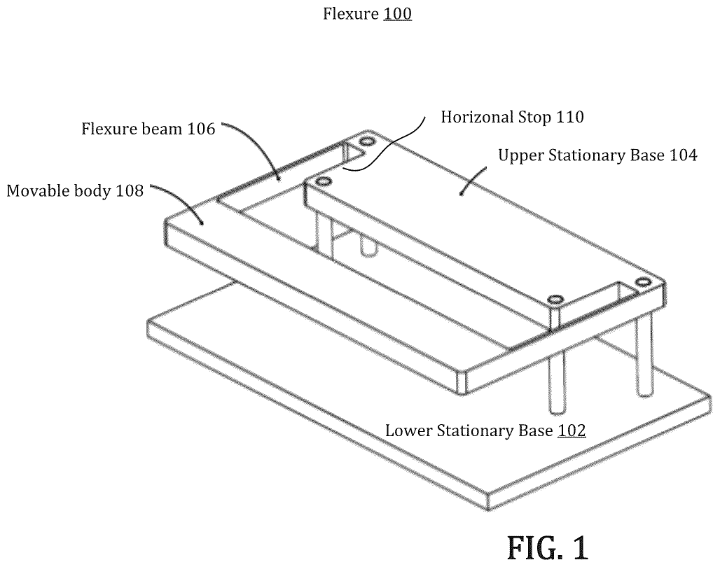

A flexure 100, shown in FIG. 1, includes a lower stationary base 102, an upper stationary base 104, a pair of flexure beams 106, and a movable body 108. Flexure beams 106 are flexible in that they can permit horizontal and vertical motion of body 108 in response to force applied in those directions to body 108. Lower stationary base 102 serves as a vertical motion stop to limit stress on flexure beams 106. Likewise, left and right side of upper station base 104 serve as horizontal stops for flexure beams 106.

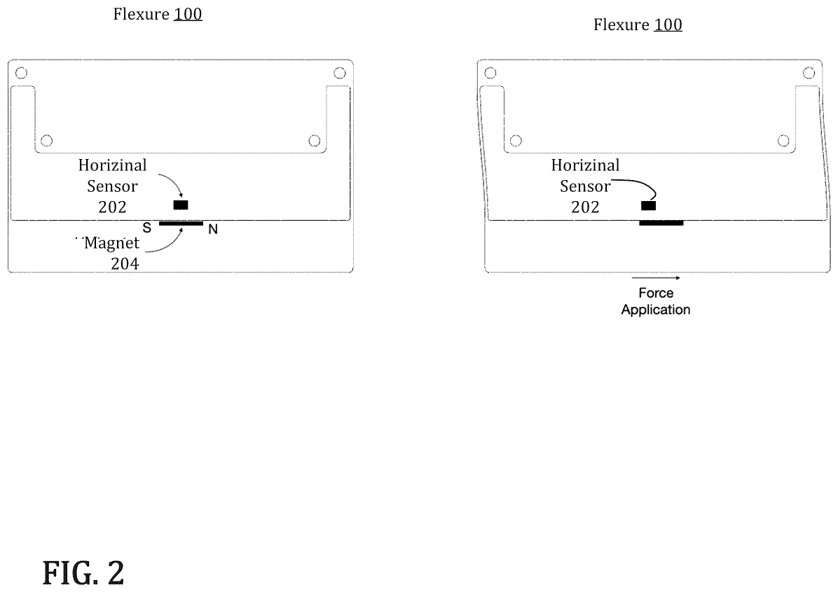

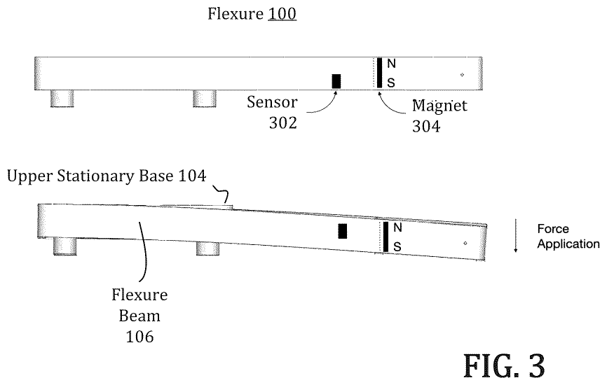

Flexure 100 is shown in FIG. 2 both with (left) and without (right) a leftward force applied. The positions of a Hall-effect sensor 202 on upper stationary body 104 and an associated magnet 204 on movable body 108 for evaluating horizontal position are also indicated in FIG. 2. Flexure 100 is shown in FIG. 3 both with (bottom) and without (top) vertical force applied. The position of a Hall-effect sensor 302 on upper stationary base 104 for evaluating vertical position of a magnet 304 on movable body 108 is indicated in FIG. 3.

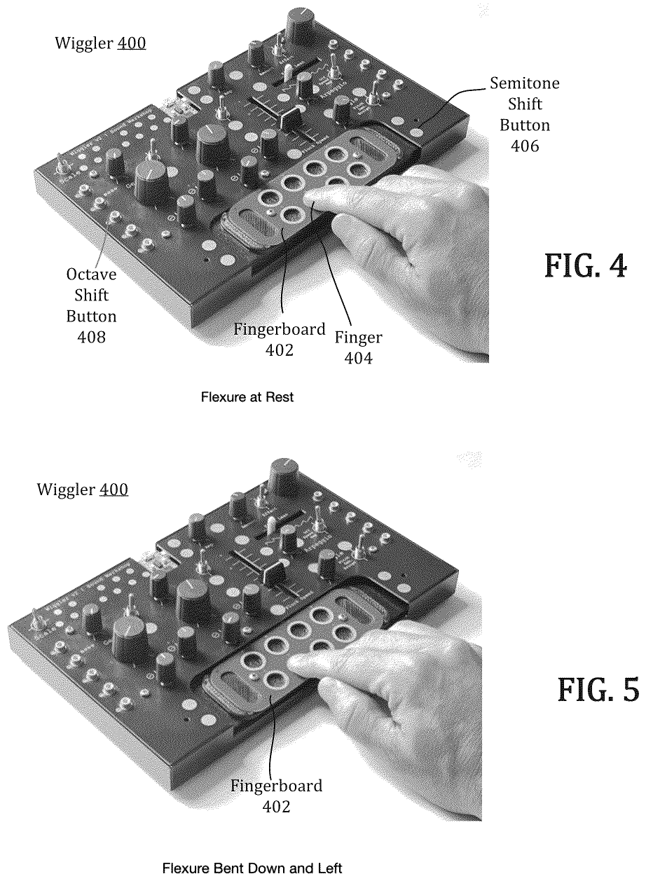

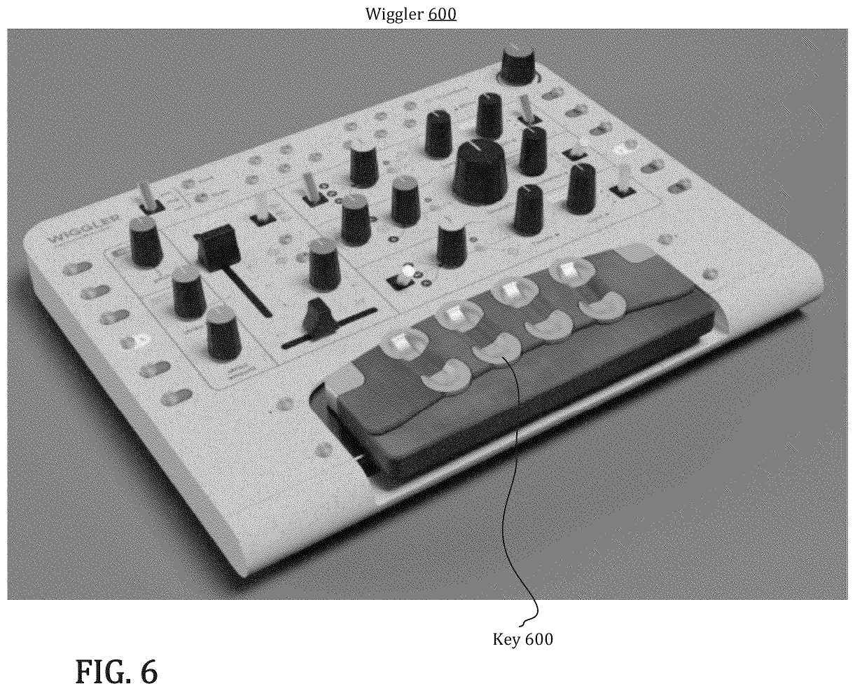

A prototype Wiggler 400 is shown in FIGS. 4 and 5. A fingerboard 402 is mounted on flexure 100 (not separately shown in FIGS. 4 and 5). A finger 404 is shown pressing one of eight keys 406 of fingerboard 402, corresponding to eight notes of an octave of a C-Major or other scale. In FIG. 4, fingerboard 402 is shown with the flexure is rest position. In FIG. 5, fingerboard 402 is shown with the flexure bent down and to the left. Pairs of buttons 406 to the left and right of fingerboard shift notes a semitone up or down, e.g., to play sharps and flats. As the fingerboard 402 is limited to one octave, five octave buttons 408 are provided both on the left (e.g., for right-handed players) and on the right (e.g., for left-handed players) to permit melodies to extend multiple octaves. A more recent prototype Wiggler 600 is shown in FIG. 6 with key 602 having finger-shaped contours permitting fingers to slide easily between top row keys and bottom row keys.

The illustrated embodiments, variations thereon, and modification thereto are provided for by the present invention, the scope of which is defined by the accompanying claims.

What is claimed is:

1. A system comprising:
a stationary base;
a movable body; and
a parallel pair of flexure beams, each flexure beam being mechanically connected to the stationary base and the movable body so as to provide for two-dimensional motion of the body relative to the stationary base.
